(19) United States
(12) Patent Application Publication
(10) Pub. No.: US 2015/0088441 A1
(43) Pub. Date: Mar. 26, 2015

(54) ENERGY USAGE ESTIMATION DEVICE AND ENERGY USAGE ESTIMATION METHOD

(71) Applicants: Masanori Nakata, Tokyo (JP); Makoto Katsukura, Tokyo (JP); Masaaki Yabe, Tokyo (JP); Noriyuki Kushiro, Tokyo (JP)

(72) Inventors: Masanori Nakata, Tokyo (JP); Makoto Katsukura, Tokyo (JP); Masaaki Yabe, Tokyo (JP); Noriyuki Kushiro, Tokyo (JP)

(73) Assignee: MITSUBISHI ELECTRIC CORPORATION, Tokyo (JP)

(21) Appl. No.: 14/367,595

(22) PCT Filed: Dec. 28, 2011
(86) PCT No.: PCT/JP2011/080527

§ 371 Date: Jun. 20, 2014

(51) Int. Cl. G01R 21/06

(52) U.S. Cl. CPC G01R 21/06
USPC 702/61

(57) ABSTRACT

A power measure calculates, based on a current and a voltage measured at a predetermined location in a power supply line, active power and apparent power for each predetermined time period based on utilization of plural kinds of electric facilities connected to the power supply line. A data memory accumulates and stores data regarding the active power and the apparent power calculated by the power measure in a time-series manner. A variation detector analyzes data regarding the active power by what corresponds to a predetermined time period and stored in the data memory to detect a time slot at which there is an operation change in any one of the electric facilities. A distribution estimator calculates, when the variation detector detects the time slot, a power factor in the time slot, and estimates power consumption for each kind of the electric facilities in the time slot.

### TECHNICAL FIELD

The present disclosure relates to a technology of estimating an energy usage quantity for each electric facility from a total energy usage quantity consumed by multiple different kinds of electric facilities.

### BACKGROUND ART

Recently, reasonable energy usage is strongly requested for a corporate business (a business operator and the like) that consumes environmental energy to operate the business. Hence, it is necessary for the business operator and the like to suitably understand and manage the energy usage quantity for each kind of electric facilities (for example, lighting devices, and air-conditioners) in a factory, a commercial complex, and the like.

For example, Patent Literature 1 discloses an energy distribution calculating device that estimates the energy consumption quantity for each device from the total energy consumption quantity of multiple devices. This energy distribution calculating device includes a first database that stores an individual consumption pattern indicating a change over time in the energy consumption quantity for each of the multiple devices, measuring means for measuring a change over time in the total energy consumption quantity of the multiple devices to obtain total consumption time-series data, a pattern selector that selects at least one individual consumption pattern for each device in such a way that the total becomes most similar to the total consumption time-series data, and a distribution calculator that estimates individual consumption time-series data indicating a change over time in the energy consumption quantity actually consumed by each device based on the individual consumption pattern selected for each device and the total consumption time-series data.

### CITATION LIST

### Patent Literature

Patent Literature 1: Unexamined Japanese Patent Application Kokai Publication No. 2011-176984

### SUMMARY OF INVENTION

### Technical Problem

According to the technology disclosed in Patent Literature 1, it is necessary to extract, for each device subjected to individual measurement, individual consumption pattern indicating a change over time in the energy consumption quantity in advance, and to register the extracted pattern in the first database. When, however, a large number of devices are utilized like a building, a factory, and a commercial facility, it is not easy to prepare the consumption pattern for each device. Hence, there is a desire in practice for a development of a new technology that can easily estimate the energy usage quantity for each kind of the electric facility through a new scheme.

The present disclosure has been made in view of the foregoing circumstances, and it is an objective of the present disclosure to provide an energy usage estimation device and an energy usage estimation method which can easily and precisely estimate the energy usage quantity for each electric facility from the total energy usage quantity consumed by multiple different kinds of electric facilities.

### Solution to Problem

To accomplish the above objective, an energy usage estimation device according to the present disclosure includes:

a power measure that calculates, based on a current and a voltage measured at a predetermined location in a power supply line, active power and apparent power for each predetermined time based on utilization of plural kinds of electric facilities connected to the power supply line;

a data memory that accumulates and stores data regarding the active power and the apparent power calculated by the power measure in a time-series manner;

a variation detector that analyzes data regarding the active power by what corresponds to a predetermined time period and stored in the data memory to detect a time slot at which there is an operation change in any one of the electric facilities; and

a distribution estimator which calculates, when the variation detector detects the time slot, a power factor in the time slot, and which estimates power consumption for each kind of the electric facilities in the time slot based on the calculated power factor and a threshold set in advance for each kind of the electric facilities.

### Advantageous Effects of Invention

According to the present disclosure, data regarding measured active power by what corresponds to a predetermined time period is analyzed to detect a time slot at which there is an operation change in any one electric facility. Next, a power factor in the detected time slot is calculated, and power consumption for each kind of the electric facilities in that time slot is estimated based on the calculated power factor and a threshold set in advance in accordance with the kind of the electric facilities. Hence, it becomes possible to easily and precisely estimate the energy usage quantity for each kind of electric facilities.

### BRIEF DESCRIPTION OF DRAWINGS

FIG. 1 is a diagram illustrating a configuration of an energy usage estimation device according to Embodiment 1 of the present disclosure;

FIG. 2 is a diagram for explaining a measuring-gauge transformer and a measuring-gauge current transformer;

FIG. 3 is a block diagram illustrating a configuration of a main block according to Embodiment 1;

FIG. 4 is a diagram for explaining a variation detecting method according to Embodiment 1;

FIG. 5 is a diagram for explaining a power factor;

FIG. 6 is a flowchart illustrating a procedure of a power consumption estimating processing executed by the main block according to Embodiment 1;

FIG. 7 is a block diagram illustrating a configuration of a main block according to Embodiment 2;

FIG. 8 is a diagram for explaining a variation detecting method according to Embodiment 2;

FIG. 9 is a (first) graph indicating an estimation result of power consumption through the same method as that of an energy usage estimation device according to Embodiment 2;

FIG. 10 is a (second) graph indicating an estimation result of power consumption through the same method as that of the energy usage estimation device according to Embodiment 2; and

FIG. 11 is a block diagram illustrating a configuration of a main block according to Embodiment 3.

### DESCRIPTION OF EMBODIMENTS

Embodiments of the present disclosure will be explained in detail with reference to the accompanying drawings.

### Embodiment 1

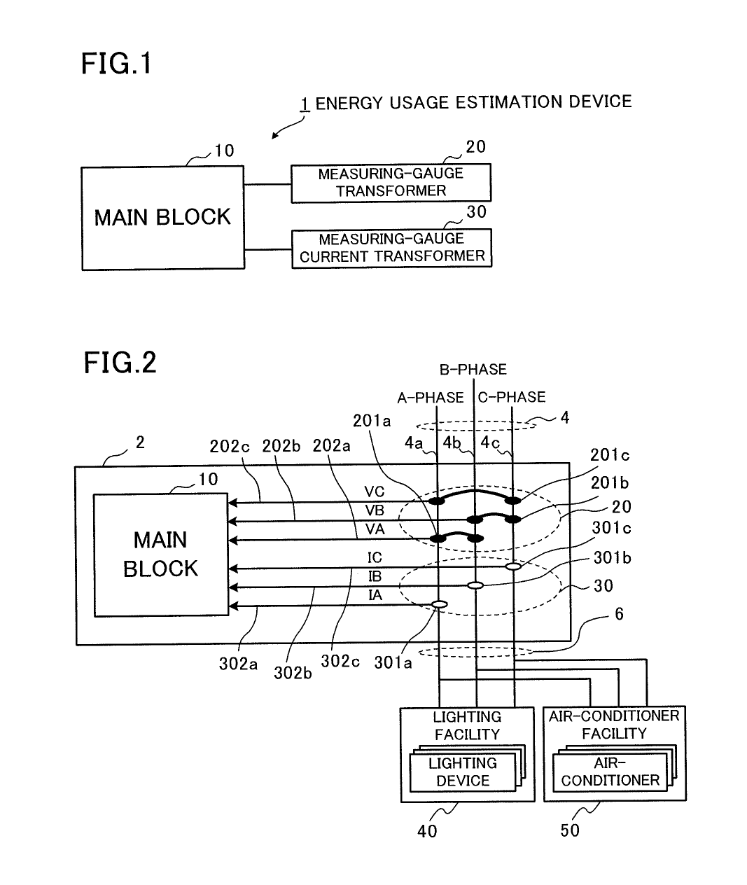

FIG. 1 is a block diagram illustrating a configuration of an energy usage estimation device 1 according to Embodiment 1 of the present disclosure. This energy usage estimation device 1 includes a main block 10, a measuring-gauge transformer 20, and a measuring-gauge current transformer 30. The energy usage estimation device 1 is installed in, for example, a building, a factory, and a commercial facility (hereinafter, referred to as a building and the like), and is a device that estimates the energy usage quantity consumed for each electric facility in the building and the like.

More specifically, as illustrated in FIG. 2, the energy usage estimation device 1 is installed near a power distribution board 2 in a consumer's location like a building and the like, and measures a total power consumption by a lighting facility 40 and an air-conditioner facility 50 utilized in the building and the like. The lighting facility 40 includes multiple lighting devices, while the air-conditioner facility 50 includes multiple air-conditioners (including equal to or greater quantity than one outdoor device and multiple indoor devices). Since the lighting facility 40 and the air-conditioner facility 50 do not consume energy other than electric power, the aforementioned total power consumption is equivalent to a total of the energy consumption (energy usage quantity) by the lighting facility 40 and the air-conditioner facility 50. In this embodiment, the start and stop of the operation of the whole lighting devices constituting the lighting facility 40 are performed at the same timing. Likewise, the start and stop of the operation of the whole air-conditioners constituting the air-conditioner facility 50 are performed at the same timing.

The power distribution board 2 is connected to the power system of an electric power supplier through leading wires 4. In addition, the power distribution board 2 is connected with power supply lines 6 to supply power to the lighting facility 40 and the air-conditioner facility 50.

As illustrated in FIG. 2, the measuring-gauge transformer 20 includes an A-phase measuring-gauge transformer 201a, a B-phase measuring-gauge transformer 201b, and a C-phase measuring-gauge transformer 201c. In addition, the measuring-gauge current transformer 30 includes an A-phase measuring-gauge current transformer 301a, a B-phase measuring-gauge current transformer 301b, and a C-phase measuring-gauge current transformer 301c.

The measuring-gauge transformer 201a has the primary side connected between an A-phase 4a and a B-phase 4b, and outputs, from the secondary side, a voltage VA similar to a voltage between the A-phase 4a and the B-phase 4b. The secondary side of the measuring-gauge transformer 201a is connected to the main block 10 through a connection line 202a like a coaxial cable. The measuring-gauge transformer 201b has the primary side connected between the B-phase 4b and a C-phase 4c, and outputs, from the secondary side, a voltage VB similar to a voltage between the B-phase 4b and the C-phase 4c. The secondary side of the measuring-gauge transformer 201b is connected to the main block 10 through a connection line 202b like a coaxial cable. The measuring-gauge transformer 201c has the primary side connected between the C-phase 4c and the A-phase 4a, and outputs, from the secondary side, a voltage VC similar to a voltage between the C-phase 4c and the A-phase 4a. The secondary side of the measuring-gauge transformer 201c is connected to the main block 10 through a connection line 202c like a coaxial cable.

The measuring-gauge current transformer 301a measures a current flowing in the A-phase 4a at the primary side, and outputs, from the secondary side, a current IA similar to a current in the A-phase. The secondary side of the measuring-gauge current transformer 301a is connected to the main block 10 through a connection line 302a like a coaxial cable. The measuring-gauge current transformer 301b measures a current flowing in the B-phase 4b at the primary side, and outputs, from the secondary side, a current IB similar to a current in the B-phase. The secondary side of the measuring-gauge current transformer 301b is connected to the main block 10 through a connection line 302b like a coaxial cable. The measuring-gauge current transformer 301c measures a current flowing in the C-phase 4c at the primary side, and outputs, from the secondary side, a current IC similar to a current in the C-phase. The secondary side of the measuring-gauge current transformer 301c is connected to the main block 10 through a connection line 302c like a coaxial cable. In this embodiment, as the respective measuring-gauge current transformers 301a, 301b, and 301c, measuring-gauge current transformers employing a through-type or clamp-type structure are employed.

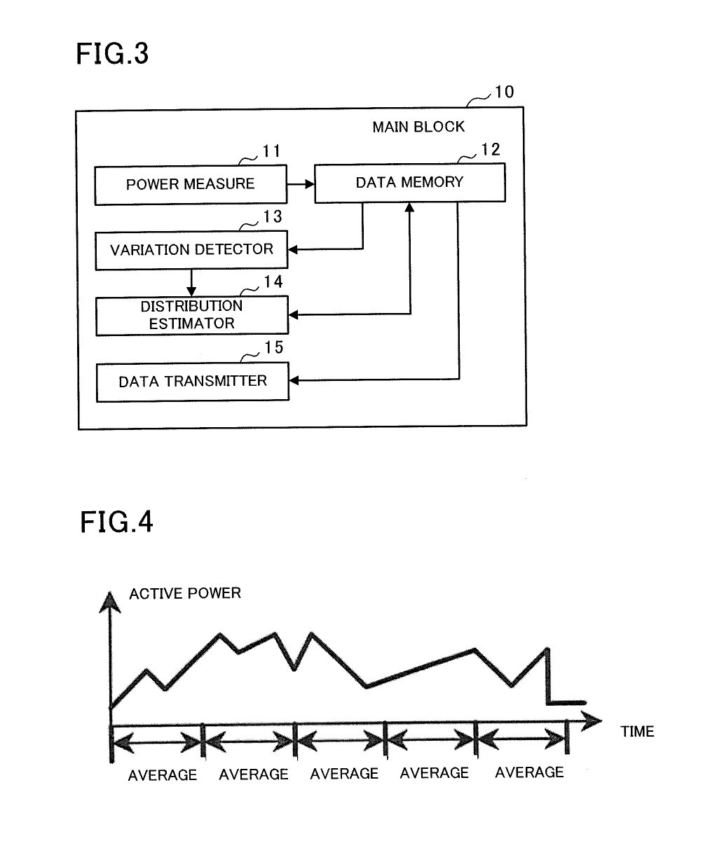

The main block 10 includes, as hardware resources, a CPU (Central Processing Unit), a ROM (Read Only Memory), a RAM (Random Access Memory), a readable/writable semiconductor memory like a flash memory, and a predetermined communication interface, and the like (all unillustrated). In addition, the main block 10 includes, as functional blocks, as illustrated in FIG. 3, a power measure 11, a data memory 12, a variation detector 13, a distribution estimator 14, and a data transmitter 15. The function of each functional block is realized by the CPU running one or multiple predetermined programs stored in the ROM or the semiconductor memory.

The power measure 11 extracts data of commercial-frequency single-cycle on a total load current based on the voltage and the current output by the measuring-gauge transformer 20 and the measuring-gauge current transformer 30, thereby measuring power for each cycle. In addition, the power measure 11 integrates such data for one minute (corresponding to 120 cycles in the case of commercial frequency=50 Hz), and calculates an average value of active power for one minute. Still further, the power measure 11 also calculates an average value of apparent power for one minute.

The apparent power (S) is, as expressed in the formula 1, a product of a voltage effective value (V) and a current effective value (I). In the formula 1, P is active power, while Q is reactive power.

[Formula 1]

S=|V∥I|=\sqrt{P²+Q²} (Formula 1)

The power measure 11 accumulates and stores, in a time-series manner, data regarding those calculated average values (active power data, apparent power data) in the data memory 12.

The variation detector 13 analyzes the active power data by what corresponds to the predetermined time period stored in the data memory 12, and detects a time slot at which there is an operation change in at least either one of the lighting facility 40 and the air-conditioner facility 50. More specifically, the variation detector 13 is activated at a predetermined timing (for example, for each predetermined time cycle), and calculates, from the active power data by what corresponds to a predetermined time period (for example, 24 hours) stored in the data memory 12, an average value for each predetermined time period (for example, 30 minutes period) as illustrated in FIG. 4. Next, the variation detector 13 sequentially focuses on the calculated average values in a time-series manner, and obtains a difference from the average value of an adjoining past time slot.

The variation detector 13 compares the absolute value of the obtained difference (active power difference) with a preset threshold (active power difference threshold), and notifies the distribution estimator 14 of the comparison result. In this case, the active power difference threshold is set to be a value that permits an estimation that the operation of at least either one of the lighting facility 40 and the air-conditioner facility 50 is started or stopped when the absolute value of the active power difference becomes greater than such a threshold. In this case, when, for example, the active power difference is a positive value, such a sign indicates that the operation of at least either one of the lighting facility 40 or the air-conditioner facility 50 is started. Conversely, when the active power difference is a negative value, such a sign indicates that the operation of at least either one of the lighting facility 40 or the air-conditioner facility 50 is stopped.

The distribution estimator 14 estimates the respective operation statuses (start, stop, in operation) of the lighting facility 40 and the air-conditioner facility 50 in a subject time slot (a time slot corresponding to the above-explained focused average value).

An explanation will now be given of an estimation rule of the operation status of the electric facility according to the present disclosure. According to the present disclosure, the operation status of each facility is estimated in view of a large difference between the power factor of the lighting facility and that of the air-conditioner facility. The power factor is a ratio of the active power to the apparent power, and it is known that in the case of an electric device like a lighting device having substantially no reactive power (Q), the power factor thereof is substantially 100%. Conversely, it is known that the power factor of air-conditioner devices is substantially 60 to 75%.

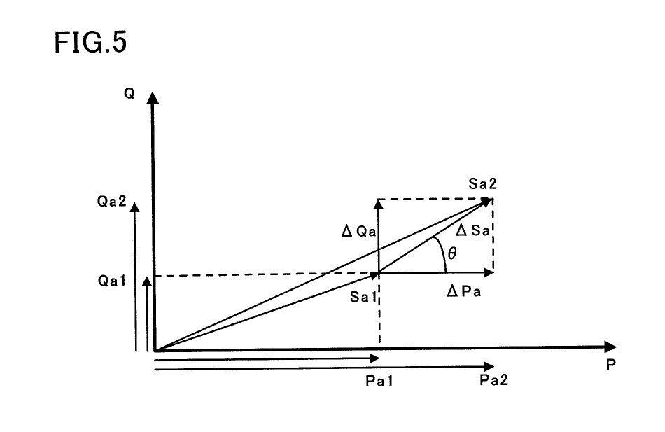

Hence, according to the present disclosure, as illustrated in FIG. 5, when power consumption (active power) (P) changes from Pa1 to Pa2 (apparent power (S) changes from Sa1 to Sa2), a power factor (cos θ) based on a difference ΔPa of the active power and a difference ΔSa of the apparent power is calculated. Next, according to the present disclosure, based on the calculated power factor and preset threshold (first threshold) for the air-conditioner facility and threshold (second threshold) for lighting facility, the respective operation statuses of the air-conditioner facility and the lighting facility are estimated.

The distribution estimator 14 estimates the respective operation statuses of the lighting facility 40 and the air-conditioner facility 50 in a subject time slot based on the aforementioned rule, and estimates respective power consumptions of the lighting facility 40 and the air-conditioner facility 50 in the subject time slot. An explanation will be given below of the processing executed by the distribution estimator 14 in more detail.

The estimation distributor 14 calculates the difference ΔSa of the apparent power when the variation detection result notified from the variation detector 13 indicates that the absolute value of the active power difference is greater than the active power difference threshold, and calculates the power factor (cos θ) in the subject time slot. Next, the distribution estimator 14 compares the calculated power factor with the above-explained first threshold (threshold for air-conditioner facility). The first threshold is set to be, for example, 0.75. As a result, when the power factor is less than the first threshold, the distribution estimator 14 sets, as the power consumption (estimated power consumption) of the air-conditioner facility 50 in that time slot, a result obtained by adding the active power difference to the last power consumption (the estimated power consumption of the air-conditioner facility 50 in the last time slot) of the air-conditioner facility 50. That is, in this case, the distribution estimator 14 estimates that there is an operation change (start or stop) of the air-conditioner facility 50 in that time slot.

Conversely, when the power factor is equal to or greater than the first threshold, the distribution estimator 14 compares the calculated power factor with the above-explained second threshold (threshold for lighting facility). For example, the second threshold is set to be 0.85. As a result, when the power factor is greater than the second threshold, the distribution estimator 14 sets, as the power consumption (estimated power consumption) of the lighting facility 40 in the subject time slot, a result obtained by adding the active power difference to the last power consumption (estimated power consumption of the lighting facility 40 in the last time slot) of the lighting facility 40. That is, in this case, the distribution estimator 14 estimates that there is an operation change of the lighting facility 40 in that time slot.

When the power factor is equal to or greater than the first threshold but is equal to or less than the second threshold, the distribution estimator 14 adds ½ of the active power difference to the last estimated power consumption of the lighting facility 40, and sets, as the estimated power consumption of the lighting facility 40 in the subject time slot, the addition result. In addition, the distribution estimator 14 adds ½ of the active power difference to the last estimated power consumption of the air-conditioner facility 50, and sets, as the estimated power consumption of the air-conditioner facility 50 in the subject time slot, the addition result. That is, in this case, the distribution estimator 14 estimates that there are operation changes in both lighting facility 40 and air-conditioner facility 50 in the subject time slot.

When the variation detection result notified from the variation detector 13 indicates that the absolute value of the active power difference is equal to or less than the active power difference threshold, the distribution estimator 14 estimates that there is no operation change in both lighting facility 40 and air-conditioner facility 50 (that is, currently in operation or under suspension). Hence, the distribution estimator 14 calculates respective estimated power consumption in accordance with the last operation statuses of the lighting facility 40 and the air-conditioner facility 50. When, for example, in the last time slot, the lighting facility 40 was in operation and the air-conditioner facility 50 was under suspension, the distribution estimator 14 sets, as the estimated power consumption of the lighting facility 40 in the subject time slot, a result obtained by adding the active power difference to the last estimated power consumption of the lighting facility 40. In this case, moreover, the distribution estimator 14 sets the estimated power consumption of the air-conditioner facility 50 in the subject time slot to be zero.

Conversely, when, in the last time slot, the air-conditioner facility 50 was in operation but the lighting facility 40 was under suspension, the distribution estimator 14 sets, as the estimated power consumption of the air-conditioner facility 50 in the subject time slot, a result obtained by adding the active power difference to the last estimated power consumption of the air-conditioner facility 50. In this case, moreover, the distribution estimator 14 sets the estimated power consumption of the lighting facility 40 in the subject time slot to be zero.

Still further, when, in the last time slot, both lighting facility 40 and air-conditioner facility 50 were in operation, the distribution estimator 14 adds ½ of the active power difference to the last estimated power consumption of the lighting facility 40, and sets, as the estimated power consumption of the lighting facility 40 in the subject time slot, the addition result. In addition, the distribution estimator 14 adds ½ of the active power difference to the last estimated power consumption of the air-conditioner facility 50, and sets, as the estimated power consumption of the air-conditioner facility 50 in the subject time slot, the addition result.

Yet further, when, in the last time slot, the lighting facility 40 and the air-conditioner facility 50 were both under suspension, the distribution estimator 14 sets the respective estimated power consumption of the lighting facility 40 and the air-conditioner facility 50 in the subject time slot to be zero.

The distribution estimator 14 stores the respective estimated power consumption data of the lighting facility 40 and the air-conditioner facility 50 obtained in the aforementioned manner in the data memory 12 in a time-series manner.

The data transmitter 15 establishes a communication with an unillustrated other system, and transmits, to the other system at a predetermined timing, data that is a collection of pieces of data stored in the data memory 12 and measured and estimated for a predetermined time period (for example, 24 hours). The transmission timing is optionally settable, and may be, for example, a timing at which the other system requests data transmission or a timing for each predetermined time cycle (for example, every 24 hours).

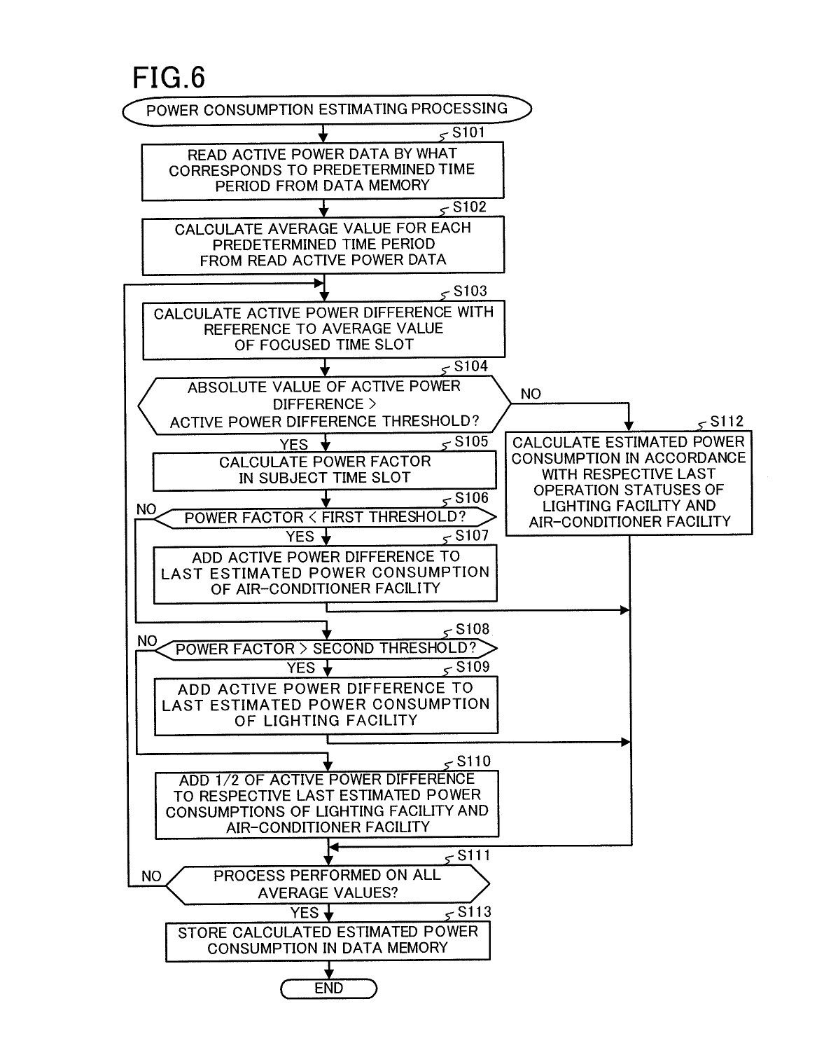

FIG. 6 is a flowchart illustrating a procedure of a power consumption estimating processing executed by the main block 10 of the energy usage estimation device 1 employing the above-explained structure. This processing is executed at a predetermined timing (for example, every day at 0:00 AM). First, the variation detector 13 reads the active power (power consumption) data by what corresponds to a predetermined time period (for example, 24 hours period) from the data memory 12 (step S101).

The variation detector 13 calculates the average value for each predetermined time period from the read active power data by what corresponds to the predetermined time period (step S102). Next, the variation detector 13 sequentially focuses on the calculated average values in time-series, and calculates a difference (active power difference) from the average value of the adjoining last time slot (step S103). Subsequently, the variation detector 13 determines whether or not the absolute value of the calculated active power difference is greater than the active power difference threshold (step S104), and notifies the distribution estimator 14 of the determination result.

When the absolute value of the active power difference is greater than the active power difference threshold (step S104: YES), the distribution estimator 14 calculates the power factor (cos θ) in the subject time slot (step S105). The distribution estimator 14 determines whether or not the calculated power factor is less than the first threshold (for example, 0.75) (step S106). Upon determination, when the power factor is less than the first threshold (step S106: YES), the distribution estimator 14 adds the active power difference to the last estimated power consumption of the air-conditioner facility 50, and sets the resultant obtained value as the estimated power consumption of the air-conditioner facility 50 in the subject time slot (step S107). Thereafter, the process by the distribution estimator 14 progresses to step S111.

Conversely, when the power factor is equal to or greater than the first threshold (step S106: NO), the distribution estimator 14 determines whether or not the power factor is greater than the second threshold (for example, 0.85) (step S108). Upon determination, when the power factor is greater than the second threshold (step S108: YES), the distribution estimator 14 adds the active power difference to the last estimated power consumption of the lighting facility 40, and sets the resultant obtained value as the estimated power consumption of the lighting facility 40 in the subject time slot (step S109). Thereafter, the process by the distribution estimator 14 progresses to the step S111.

When the power factor is equal to or greater than the first threshold but is equal to or less than the second threshold (step S106: NO and step S108: NO), the distribution estimator 14 adds ½ of the active power difference to the respective last estimated power consumptions of the lighting facility 40 and the air-conditioner facility 50 (step S110). Next, the distribution estimator 14 sets the respective results as the estimated power consumptions of the lighting facility 40 and the air-conditioner facility 50 in the subject time slot. Thereafter, the process by the distribution estimator 14 progresses to the step S111.

When the determination result in the step S104 is NO, that is, when the absolute value of the active power difference is equal to or less than the active power difference threshold, the distribution estimator 14 calculates the respective estimated power consumptions in accordance with the last operation statuses of the lighting facility 40 and the air-conditioner facility 50 as explained above (step S112). Thereafter, the process by the distribution estimator 14 progresses the process to the step S111.

In the step S111, the distribution estimator 14 determines whether or not the above-explained process was performed on all calculated average values (step S111). When the process is not performed on all average values (step S111: NO), the variation detector 13 focuses on the next average value in time-series, and calculates the active power difference (step S103). Subsequently, the above-explained respective processes are repeated.

Conversely, when the process was performed on all average values (step S111: YES), the distribution estimator 14 stores, in the data memory 12 in a time-series manner, the estimated power consumption data regarding the lighting facility 40 and the air-conditioner facility 50 calculated for each predetermined time period (for example, 30 minutes period) in the subject time period (for example, 24 hours period) (step S113).

As explained above, according to the energy usage estimation device 1 according to this embodiment of the present disclosure, the variation detector 13 calculates an average value for each predetermined time period (for example, 30 minutes period) from the measured active power data stored in the data memory 12 and by what corresponds to a predetermined time period (for example, 24 hours period). Next, the variation detector 13 sequentially focuses on the calculated average values in time-series, calculates the active power difference, and compares the calculated active power difference with the active power difference threshold, thereby detecting whether or not there is a variation (operation change) in at least either one of the lighting facility 40 and the air-conditioner facility 50.

Next, when the variation is found, the distribution estimator 14 calculates the power factor of the subject time slot, and estimates the respective operation statuses of the lighting facility 40 and the air-conditioner facility 50 based on the calculated power factor, the first threshold for the air-conditioner facility, and the second threshold for the lighting facility. Next, the distribution estimator 14 estimates the respective power consumptions of the lighting facility 40 and the air-conditioner facility 50 based on the estimation results. Hence, unlike the conventional technologies, it becomes possible to easily and precisely estimate the respective energy usage quantities of the lighting facility 40 and the air-conditioner facility 50 without preparing in advance and retaining the consumption pattern for each electric facility.

Data and the like regarding the respective power consumptions of the lighting facility 40 and the air-conditioner facility 50 estimated by the distribution estimator 14 may be, for example, transmitted from the data transmitter 15 to the other terminal device and the like installed in the subject building or the like. In this case, the terminal device and the like may display and present the detail of transmitted data to the manager of the building or the like. In addition, the aforementioned data may be transmitted from the data transmitter 15 to a server operated by a service provider like an electric power supplier through a predetermined communication line. This allows the service provider to easily collect information on the power usage of the power consuming user, and to utilize the information to establish a new service. As a result, it becomes possible for the service provider to provide various information services to the power consuming user.

For example, one of the important information for the electric power supplier and the like is information regarding the configurations of the lighting facility and the air-conditioner facility and the actual usages thereof. In particular, in the case of, for example, a building, if the detail of the actual electric usage, energy saving can be progressed. The energy usage estimation device 1 of this embodiment is a useful device that can cope with such needs.

### Embodiment 2

Next, an explanation will be given of an energy usage estimation device according to Embodiment 2 of the present disclosure. The energy usage estimation device of Embodiment 2 has a difference in some functions of the main block 10 in comparison with the energy usage estimation device 1 of Embodiment 1. The other points are the same as those of the energy usage estimation device 1 of Embodiment 1.

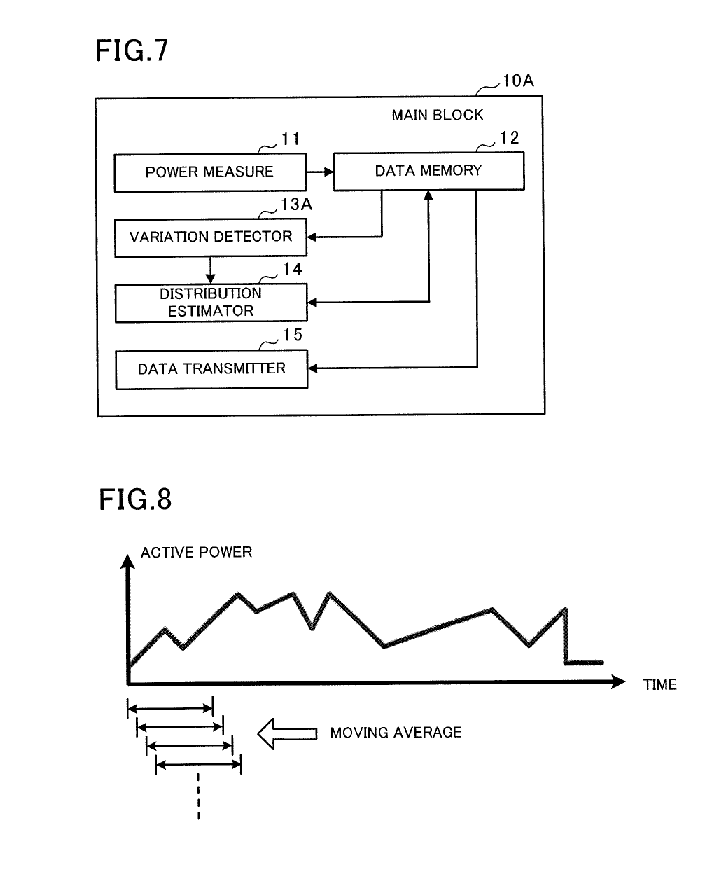

FIG. 7 is a block diagram illustrating a functional configuration of a main block 10A included in the energy usage estimation device according to this embodiment. As illustrated in FIG. 7, the main block 10A includes, unlike the main block 10 of Embodiment 1, a variation detector 13A instead of the variation detector 13. That is, the main block 10A of this embodiment employs a different scheme (variation detecting scheme) of detecting whether or not there is a variation in at least either one of the lighting facility 40 and the air-conditioner facility 50 from the main block 10 of Embodiment 1. An explanation below will be given of the variation detecting scheme according to this embodiment.

Like the variation detector 13 of Embodiment 1, the variation detector 13A is activated at a predetermined timing (for example, every day at 0:00 AM), reads active power data by what corresponds to a predetermined time period (for example, 24 hours period) and stored in the data memory 12. Next, the variation detector 13A calculates a moving average value of a predetermined length (for example, four minutes) at a predetermined movement interval (for example, an interval of one minute) from the origin (for example, a time point 24 hours before) of the read active power data as illustrated in FIG. 8.

Next, the variation detector 13A sequentially focuses on the calculated moving average values in a time-series manner, and obtains a difference from the moving average value of the adjoining last time slot. The variation detector 13A compares the absolute value of the obtained difference (that is, the active power difference) with a preset threshold (active power difference threshold), and notifies the distribution estimator 14 of a comparison result. In this case, the active power difference threshold is set to be a value that permits an estimation that the operation of at least either one of the lighting facility 40 and the air-conditioner facility 50 is started or stopped when the absolute value of the active power difference becomes greater than such a threshold like Embodiment 1. The active power difference threshold of Embodiment 2 may be consistent with the active power difference threshold of Embodiment 1, or may be a different value.

The estimation rule of the operation status and the estimation scheme of the power consumption by the distribution estimator 14 are the same as those of the distribution estimator 14 of Embodiment 1, and thus the explanation thereof will be omitted.

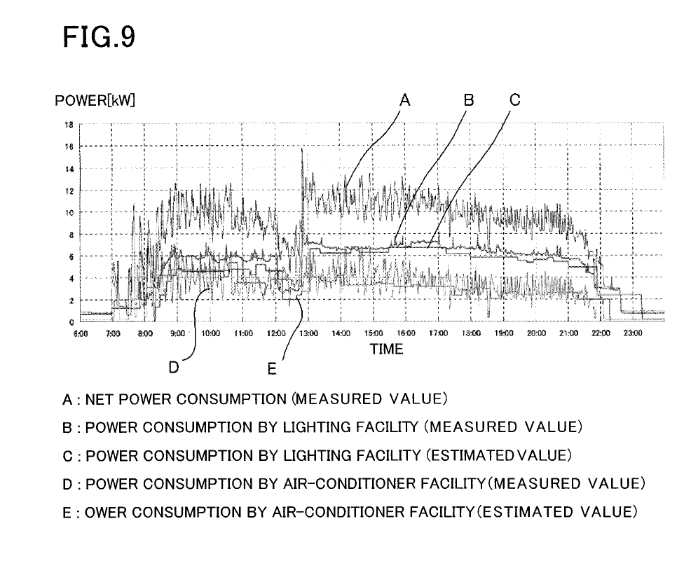

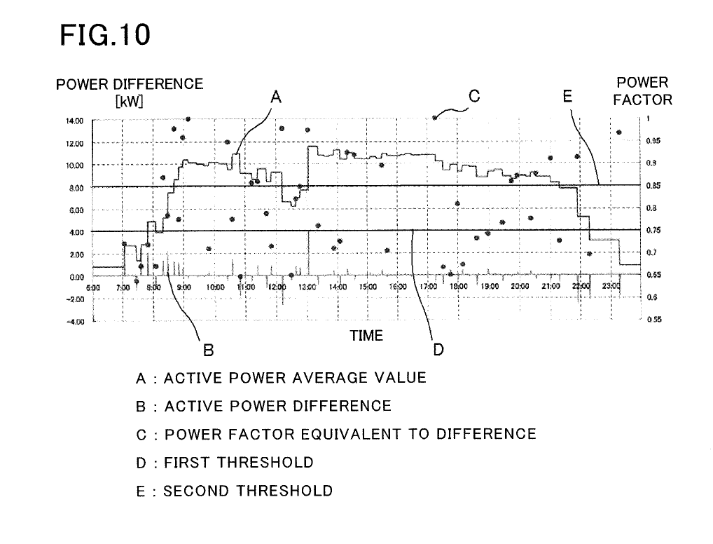

FIGS. 9 and 10 are each a graph representing an estimation result of power consumption through the same scheme as that of the energy usage estimation device according to this embodiment. Based on those results, it becomes clear that power consumption is precisely estimated in both cases of the lighting facility and the air-conditioner facility.

As explained above, according to the energy usage estimation device according to this embodiment, a variation (operation change) in the lighting facility 40 and the air-conditioner facility 50 is detected through a comparison of the difference of the moving average value with the threshold. Hence, an operation change is precisely detectable, resulting in the improvement of the estimation precision of power consumption.

### Embodiment 3

Next, an explanation will be given of an energy usage estimation device according to Embodiment 3 of the present disclosure. The energy usage estimation device according to Embodiment 3 has a difference in some functions of the main block 10 in comparison with the energy usage estimation device 1 according to Embodiment 1. The other points are the same as those of the energy usage estimation device 1 according to Embodiment 1.

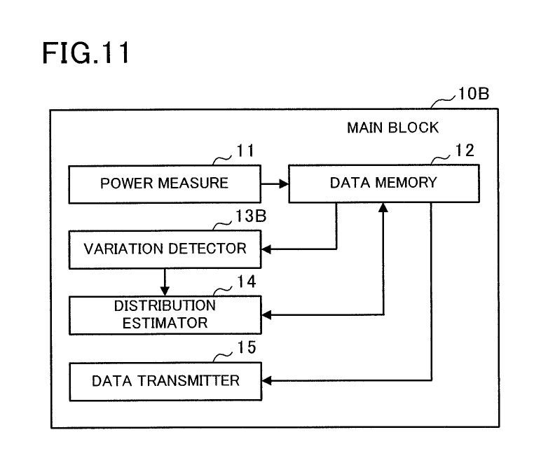

FIG. 11 is a block diagram illustrating a functional configuration of a main block 10B included in the energy usage estimation device according to this embodiment. As illustrated in FIG. 11, the main block 10B according to this embodiment differs from both main blocks 10, 10A of Embodiments 1 and 2, and includes a variation detector 13B instead of the variation detectors 13, 13A. That is, the main block 10B according to this embodiment employs a difference variation detecting scheme for the lighting facility 40 and the air-conditioner facility 50 from the main blocks 10, 10A according to Embodiments 1 and 2. An explanation below will be given of the variation detecting scheme according to this embodiment.

Like the variation detectors 13, 13A according to Embodiments 1 and 2, the variation detector 13B is activated at a predetermined timing (for example, every day at 0:00 AM), and reads active power data by what corresponds to a predetermined time period (for example, 24 hours period) stored in the data memory 12. Next, a low-pass filter (digital filter) operation is, as expressed in the formula 2 below, performed on an i-th active power sequentially extracted from the active power data at a predetermined time interval.

Yᵢ=c*Xᵢ₋₁+(1−c)*Xᵢ (Formula 2)

where: c is a filter coefficient (for example, 0.2).

Next, the variation detector 13B obtains a difference between the active power (Yᵢ) having undergone the low-pass filter operation and the last active power (Yᵢ₋₁) having undergone the low-pass filter operation. The variation detector 13B compares the absolute value of the obtained difference (that is, the active power difference) with a preset threshold (active power difference threshold), and notifies the distribution estimator 14 of a comparison result. In this case, the active power difference threshold is set to be a value that permits an estimation that there is an operation change in at least either one of the lighting facility 40 and the air-conditioner facility 50 when the absolute value of the active power difference becomes greater than such a threshold like Embodiments 1 and 2. The active power difference threshold of Embodiment 3 may be consistent with that of Embodiment 1 or 2, or may be a difference value therefrom.

The estimation rule of the operation status and the estimation scheme of power consumption by the distribution estimator 14 are the same as those of the distribution estimators 14 according to Embodiments 1 and 2, and thus the explanation thereof will be omitted.

As explained above, according to the energy usage estimation device of this embodiment, a difference obtained based on the low-pass filter operation is compared with the threshold to detect a variation (operation change) in the lighting facility 40 and the air-conditioner facility 50.

Next, when there is a variation, like Embodiments 1 and 2, the respective operation statuses of the lighting facility 40 and the air-conditioner facility 50 are estimated, and the respective power consumptions of the lighting facility 40 and the air-conditioner facility 50 are estimated based on the former estimation results. Hence, unlike the conventional technologies, it is possible to easily and precisely estimate respective energy usage quantities of the lighting facility 40 and the air-conditioner facility 50 without preparing in advance and holding a consumption pattern for each electric facility.

The present disclosure is not limited to the above-described embodiments, for various variations are possible without deviating from the scope of the present disclosure.

For example, electric facilities having power consumption that can be estimated through the present disclosure are not limited to lighting facility and air-conditioner facility. When there is a remarkable difference in respective power factors, the present disclosure is applicable to a combination of various electric facilities.

Various embodiments and modifications are available to the present disclosure without departing from the broad sense of spirit and scope of the present disclosure. The above-described embodiments are given for explaining the present disclosure and do not confine the scope of the present disclosure. In other words, the scope of the present disclosure is set forth by the scope of claims, not by the above-described embodiments. Various modifications made within the scope of claims and scope of significance of the invention equivalent thereto are considered to fall under the scope of the present disclosure.

### INDUSTRIAL APPLICABILITY

The present disclosure is suitable applicable to, as a device that estimates respective power consumptions of a lighting facility and an air-conditioner facility, not only a building, a factory, and commercial facilities, but also standard homes, and the like.

### REFERENCE SIGNS LIST

1 Energy usage estimation device
10, 10A, 10B Main block
11 Power measure
12 Data memory
13, 13A, 13B Variation detector
14 Distribution estimator
15 Data transmitter
20 Measuring-gauge transformer
30 Measuring-gauge current transformer
40 Lighting facility
50 Air-conditioner facility
201a Measuring-gauge transformer (for A-phase)
201b Measuring-gauge transformer (for B-phase)
201c Measuring-gauge transformer (for C-phase)
202a to 202c Connection line
301a Measuring-gauge current transformer (for A-phase)
301b Measuring-gauge current transformer (for B-phase)
301c Measuring-gauge current transformer (for C-phase)
302a to 302c Connection line

1. An energy usage estimation device comprising:
a power measure that calculates, based on a current and a voltage measured at a predetermined location in a power supply line, active power and apparent power for each predetermined time period based on utilization of plural kinds of electric facilities connected to the power supply line;
a data memory that accumulates and stores data regarding the active power and the apparent power calculated by the power measure in a time-series manner;
a variation detector that analyzes data regarding the active power by what corresponds to a predetermined time period and stored in the data memory to obtain, at a predetermined time interval, an active power difference that indicates a variance of the active power and detect, based on the obtained active power difference, a time slot at which there is an operation change in any one of the electric facilities; and
a distribution estimator which calculates, when the variation detector detects the time slot, a power factor in the time slot, and which estimates power consumption for each kind of the electric facilities in the time slot based on the calculated power factor and a threshold set in advance for each kind of the electric facilities.

2. The energy usage estimation device according to claim 1, wherein the variable detector:
sequentially calculates an average value for each predetermined time period from the data regarding the active power by what corresponds to the predetermined time period;
selects the calculated average value in a time-series manner,
obtains, as the active power difference, a difference between the selected average value and an average value of a previous time slot to the time slot corresponding to the selected average value; and
compares an absolute value of the obtained active power difference with a preset threshold to detect whether or not there is an operation change in any one of the electric facilities in the time slot corresponding to the selected average value.

3. The energy usage estimation device according to claim 1, wherein the variation detector:
sequentially calculates a moving average with a predetermined length from the data regarding the active power by what corresponds to the predetermined time period;
selects the calculated moving average in a time-series manner;
obtains, as the active power difference, a difference between the selected moving average and a moving average of a previous time slot to the time slot corresponding to the selected moving average; and
compares an absolute value of the obtained active power difference with a preset threshold to detect whether or not there is an operation change in any one of the electric facilities in the time slot corresponding to the selected moving average.

4. The energy usage estimation device according to claim 1, wherein the variation detector:
performs a predetermined low-pass filter operation on active power extracted from, at a predetermined time interval, the data regarding the active power by what corresponds to the predetermined time period to obtain active power having undergone low-pass filtering;
obtains, as the active power difference, a difference between the presently obtained active power having undergone low-pass filtering and active power having undergone low-pass filtering and obtained previously; and
compares an absolute value of the obtained active power difference with a preset threshold to detect whether or not there is an operation change in any one of the electric facilities in the time slot corresponding to the extracted active power.

5. The energy usage estimation device according to claim 1, further comprising a data transmitter that transmits, to another device, data containing power consumption for each kind of the electric facilities estimated by the distribution estimator through a predetermined communication scheme.

6. An energy usage estimation method comprising:
calculating, based on a current and a voltage measured at a predetermined location in a power supply line, active power and apparent power for each predetermined time period based on utilization of plural kinds of electric facilities connected to the power supply line;
accumulating and storing data regarding the active power and the apparent power calculated in a time-series manner and in a predetermined memory;
analyzing data regarding the active power by what corresponds to a predetermined time period and stored in the memory to obtain, at a predetermined time interval, an active power difference that indicates a variance of the active power and detect, based on the obtained active power difference, a time slot at which there is an operation change in any of the electric facilities; and
calculating, when the time slot is detected, a power factor in the time slot, and estimating power consumption for each kind of the electric facilities in the time slot based on the calculated power factor and a threshold set in advance for each kind of the electric facilities.

7. The energy usage estimation device according to claim 1, wherein:
the electric facilities include a first electric facility and a second electric facility wherein a power factor of the second electric facility is greater than a power factor of the first electric facility;
the threshold includes a first threshold determined based on the power factor of the first electric facility and a second threshold determined based on the power factor of the second electric facility; and
the distribution estimator estimates that:
when the calculated power factor is less than the first threshold, there is an operation change in the first electric facility;
when the calculated power factor is greater than the second threshold, there is an operation change in the second electric facility; and
when the calculated power factor is equal to or greater than the first threshold but is equal to or less than the second threshold, there are operation changes in both of the first and second electric facilities.

8. The energy usage estimation device according to claim 7, wherein the distribution estimator:
estimates first power consumption, power consumption of the first electric facility in the time slot at which there is an operation change of the first electric facility, to be a first value obtained by adding the active power difference to previously-estimated power consumption of the first electric facility, when the calculated power factor is less than the first threshold;
estimates second power consumption, power consumption of the second electric facility in the time slot at which there is an operation change of the second electric facility, to be a second value obtained by adding the active power difference to previously-estimated power consumption of the second electric facility, when the calculated power factor is greater than the second threshold; and
estimates the first power consumption to be a third value obtained by adding ½ of the active power difference to the previously-estimated power consumption of the first electric facility, and the second power consumption to be a fourth value obtained by adding ½ of the active power difference to the previously-estimated power consumption of the second electric facility, when the calculated power factor is equal to or greater than the first threshold but is equal to or less than the second threshold.

9. The energy usage estimation method according to claim 6, wherein:
the electric facilities include a first electric facility and a second electric facility wherein a power factor of the second electric facility is greater than a power factor of the first electric facility;
the threshold includes a first threshold determined based on the power factor of the first electric facility and a second threshold determined based on the power factor of the second electric facility; and
the estimating the power consumption includes estimating that:
when the calculated power factor is less than the first threshold, there is an operation change in the first electric facility;
when the calculated power factor is greater than the second threshold, there is an operation change in the second electric facility; and
when the calculated power factor is equal to or greater than the first threshold but is equal to or less than the second threshold, there are operation changes in both of the first and second electric facilities.
